(19) United States
(12) Patent Application Publication
(10) Pub. No.: US 2024/0175960 A1
(43) Pub. Date: May 30, 2024

(54) HYBRID CURRENT SENSE SYSTEM

(71) Applicant: Analog Devices International Unlimited Company, Limerick (IE)

(72) Inventors: Luigi Franchini, Rimini (IT); Onno Martens, Hamburg (DE); Roberto Casiraghi, Milano (IT)

(73) Assignee: Analog Devices International Unlimited Company, Limerick (IE)

(21) Appl. No.: 18/386,170

(22) Filed: Nov. 1, 2023

Related U.S. Application Data
(60) Provisional application No. 63/428,575, filed on Nov. 29, 2022.

(51) Int. Cl. G01R 35/00; G01R 3/00; G01R 19/00; G01R 19/22

(52) U.S. Cl. CPC G01R 35/005; G01R 3/00; G01R 19/0038; G01R 19/22

(57) ABSTRACT

A hybrid current sense system and methods can comprise: a switch coupled to a phase output and coupled to a voltage rail; an amplifier coupled to the switch and the amplifier configured to detect current information of the switch; a current detector coupled between the switch and the voltage rail, the current detector configured to determine a measured current for the switch; and a current calibrator configured to calibrate the current information for the switch based on the measured current.

### TECHNICAL FIELD

This disclosure relates to three-phase electric motor drivers, more particularly to three-phase electric motor drivers implementing advanced control methods.

### BACKGROUND

Industries ranging from manufacturing, health care, and military to consumer products and automotive utilize and rely on electric motors. Electric motors are found in arial drones, electric cars, and data centers.

The three-phase brushless DC motor is the primary electric motor used in many of these applications as they generally have higher torque, speed, and efficiency. Furthermore, these electric motors are capable of precise control when they are used with advanced control methods such as sensorless field-oriented control and direct torque control, for example.

These advanced control methods require precise monitoring of motor parameters including current, which is essential for both field-oriented control and direct torque control. Precise current sensing circuitry tend to increase complexity, cost, and circuit footprint.

As an extension of the electronics industry, three-phase brushless DC motors and their control circuitry have come under ever-increasing commercial competitive pressures demanding miniaturization and low cost. Ensuring smaller, more cost effective control circuitry is an important strategy outlined in road maps for development of next generation products.

Challenges to the realization of next generation products include the large, costly, and complicated current sensing systems required to utilize advanced control methods. Illustratively, for example, sensorless field-oriented control requires precise current readings during each pulse-width modulated signal cycle for each phase, or leg, of a power inverter.

One previous multi-resistor current sensing system implemented power resistors, or shunt resistors, between a low-side drive transistor and ground for each phase in the power inverter. The power resistors are bulky, expensive, and inefficient; but are able to provide accurate current measurements for utilizing advanced control methods.

Illustratively, the multi-resistor current sensing system for a three-phase power inverter using sensorless field-oriented control method would implement three power resistors. Each of these power resistors increase component count, component cost, design complexity, and footprint of the power stage. Each power resistor also required its own current-sense amplifier, analog-to-digital converter, and associated circuitry which further increased costs, complexity, and component count.

Another previous development was the single shunt current sensing system having a single current sense resistor coupled between all three phases of the power stage and ground. The single shunt resistor provides cost savings, a simpler board layout, and increased efficiency; but it comes at the cost of not being capable of providing the precise readings essential for advanced motor control.

When using a single shunt resistor to determine current across all three phases of a three-phase inverter, current measurements must be taken during two separate and narrow sampling windows within each pulse-width modulation cycle. These two sampling windows are further narrowed because rise and fall edges of the power transistors take time, current-sense-amplifiers used for sampling have a minimum settling time, and many DC motors have a dead zone or non-linearity in response to input voltages.

The single shunt current sensing system exhibits these problems in both high pulse-width modulation indexes and low pulse-width modulation indexes. Because the previous single shunt current sensing system requires multiple samples per pulse-width modulated signal cycle, the components used must run multiple times faster than the pulse-width modulated signal frequency while being more accurate as sampling time window constraints are much more severe than with the multi-resistor current sensing system, for example.

The single shunt current sensing system cannot provide the accurate current readings essential for advanced motor control, requires constraints on the maximum pulse-width modulated signal frequency that can be used, and is limited to power sensitive and space constrained high current applications, such as power tools, blowers, and fans.

Solutions have been long sought but these prior developments have not taught or suggested any complete solutions, and solutions to these problems have long eluded those skilled in the art. Thus, there remains a considerable need for systems and methods that can reduce cost, component count, footprint, and complexity of power-stages using advanced motor control methods.

### BRIEF DESCRIPTION OF THE DRAWINGS

The hybrid current sense system is illustrated in the figures of the accompanying drawings which are meant to be exemplary and not limiting, in which like reference numerals are intended to refer to like components, and in which:

FIG. 1 is a schematic view of the hybrid current sense system in a first embodiment.

FIG. 2 is a graphical depiction of a three-phase sinusoidal drive signal.

FIG. 3 is a timing diagram for a single pulse-width modulated signal cycle of the low-side switches of FIG. 1 at time 3-3 of FIG. 2.

FIG. 4 is a graphical view of drain to source on state resistance with respect to temperature for one of the switches of FIG. 1.

FIG. 5 is a graphical view of the drain to source on state resistance with respect to current for one of the switches of FIG. 1.

FIG. 6 is a control flow for operating the hybrid current sense system of FIG. 1.

FIG. 7 is a schematic view of the hybrid current sense system in a second embodiment.

FIG. 8 is a timing diagram for a single pulse-width modulated signal cycle for both the high-side switches and the low-side switches of FIG. 7.

FIG. 9 is a flow chart for operating the hybrid current sense system of FIG. 7.

FIG. 10 is a flow chart for manufacturing an embodiment of the hybrid current sense system.

### DETAILED DESCRIPTION

In the following description, reference is made to the accompanying drawings that form a part hereof, and in which are shown by way of illustration, embodiments in which the hybrid current sense system may be practiced. It is to be understood that other embodiments may be utilized and structural changes may be made without departing from the scope of the hybrid current sense system.

When features, aspects, or embodiments of the hybrid current sense system are described in terms of steps of a process, an operation, a control flow, or a flow chart, it is to be understood that the steps can be combined, performed in a different order, deleted, or include additional steps without departing from the hybrid current sense system as described herein.

The hybrid current sense system is described in sufficient detail to enable those skilled in the art to make and use the hybrid current sense system and provide numerous specific details to give a thorough understanding of the hybrid current sense system; however, it will be apparent that the hybrid current sense system may be practiced without these specific details.

In order to avoid obscuring the hybrid current sense system, some well-known system configurations and methods are not disclosed in detail. These well-known system configurations and methods can include sensorless field oriented control, space vector modulation, and pulse-width modulation, for example.

Likewise, the drawings showing embodiments of the system are semi-diagrammatic and not to scale and, particularly, some of the dimensions are for the clarity of presentation and are shown greatly exaggerated in the drawing FIGs. As used herein, the term system is defined as a device or method depending on the context in which it is used.

As used herein, the term couple as in “coupled” or “coupling” is defined as a direct or indirect electrical connection between elements. Similarly, “directly coupled” or “direct coupling” means direct contact between elements or an electrical connection through wires with no intervening electrical circuitry or components.

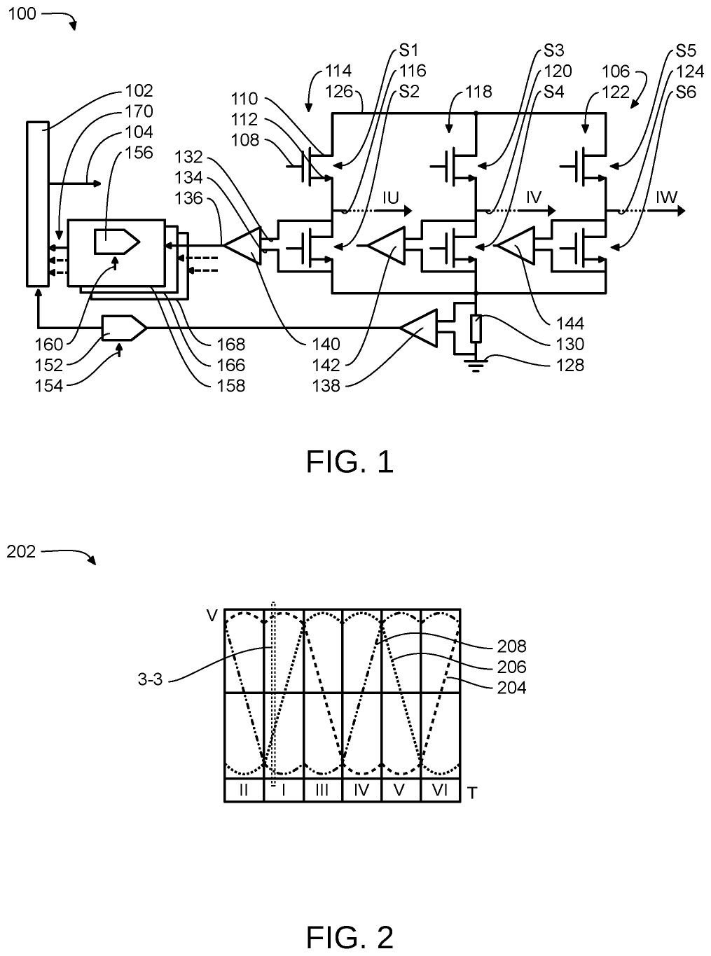

Referring now to FIG. 1, therein is shown a schematic view of the hybrid current sense system 100 in a first embodiment. The hybrid current sense system 100 is described with reference to a power stage for driving a brushless three-phase motor for illustrative purposes only. The hybrid current sense system 100 could be adapted to other applications that utilize pulse-width modulated inverters.

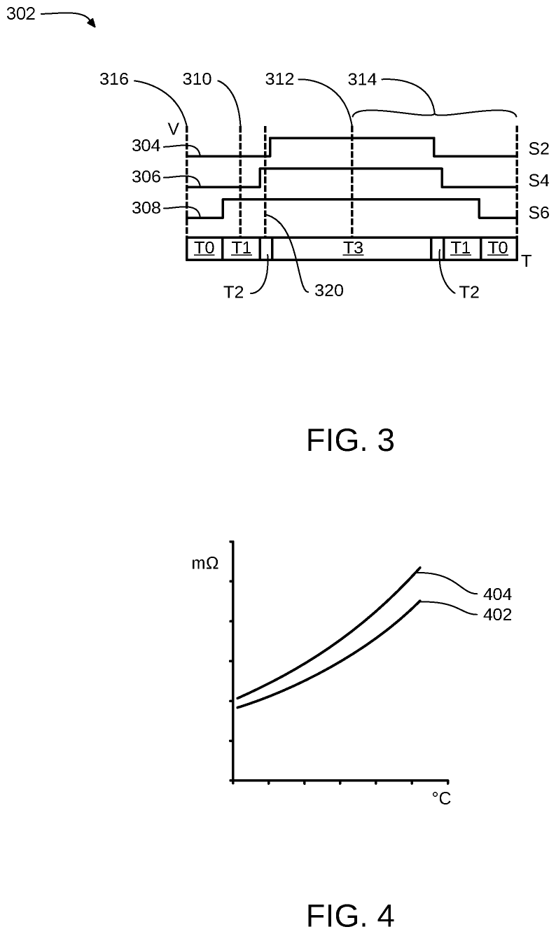

The power stage is shown including a controller 102 for generating pulse-width modulated signals on a controller output 104. The controller output 104 is connected to and controls the operation of switches within a three-phase inverter 106. The pulse-width modulated signals can, for example, be the pulse-width modulated signals to the low-side switches shown in FIG. 3.

The pulse-width modulated signals drive switches within the three-phase inverter 106 and generate the three-phase sinusoidal drive signal 202 of FIG. 2. The three-phase sinusoidal drive signal 202 is the drive signal, for example, generated to drive a three-phase brushless direct current motor (not shown).

More particularly, the switches within the three-phase inverter 106 can be transistors and are specifically depicted as NPN doped junction field effect transistors each having a gate 108, a drain 110, and a source 112. Although the transistors are depicted as NPN FETs, the hybrid current sense system 100 can apply regardless the type of switches in use.

The switches can be NFETs, complementary PFET+NFETs, eGaN FETs, or other switches. The controller output 104 can be individual connections from the controller 102 to the gate 108 for each switch within the three-phase inverter 106.

The three-phase inverter 106 can include six switches arranged into three phases, each having two switches. That is, the three-phase inverter 106 is shown having: a U-phase 114 with a U-output 116 and switches S1 and S2; a V-phase 118 with a V-output 120 and switches S3 and S4; and a W-phase 122 with a W-output 124 and switches S5 and S6.

The U-output 116, the V-output 120, and the W-output 124 are phase outputs and are described with reference to standardized terminal markings and direction of rotation for positive electrical phase sequence U-V-W of three-phase electrical motors. Each of the phase outputs, including the U-output 116, the V-output 120, and the W-output 124, can be an input for a phase of a three-phase brushless direct current motor.

The U-output 116 can correspond to a U current or IU, the V-output 120 can correspond to a V current or IV, and the W-output 124 can correspond to a W current or IW. In greater detail, S1, S3, and S5 can be considered high-side switches having their drains 110 coupled to a high voltage rail such as a source voltage 126. The source voltage 126 can be a positive DC voltage or Vm, the max voltage of the three-phase sinusoidal drive signal 202. The U-output 116 is shown coupled to both the source 112 of S1 and the drain 110 of S2. The V-output 120 is shown coupled to both the source 112 of S3 and the drain 110 of S4. The W-output 124 is shown coupled to both the source 112 of S5 and the drain 110 of S6.

Similar to the high-side switches, S2, S4, and S6 can be considered low-side switches having their sources 112 coupled to a low voltage rail such as ground 128 through a shunt resistor 130. The high voltage rail and the low voltage rail are described for clarity as the source voltage 126 and the ground 128, respectively. It is contemplated that the source voltage 126 can be any high voltage rail having a voltage higher than the low voltage rail while the ground 128 could be any low voltage rail with a voltage less than the high voltage rail.

Voltage drops across the low-side switches and the shunt resistor 130 can be detected and monitored by current-sense amplifiers, each having a positive current sensing input 132, a negative current sensing input 134, and a voltage output 136. The current-sense amplifier can be optimized for monitoring current of inductive loads, such as DC motors and solenoids, where common-mode voltages can become negative due to inductive kickback, reverse-battery conditions, or transient events.

Illustratively, for example, a first current-sense amplifier 138 can be coupled across the shunt resistor 130 for measuring a voltage drop across the shunt resistor 130 which is proportional to the current through the shunt resistor 130. Current through the shunt resistor 130 can be calculated and determined by dividing the measured voltage by the known value of the shunt resistor 130.

The positive current sensing input 132 of the first current-sense amplifier 138 can be coupled between the sources 112 of S2, S4, and S6 and the shunt resistor 130. The negative current sensing input 134 of the first current-sense amplifier 138 can be coupled between the shunt resistor 130 and ground 128.

While the current reading between the low-side switches and ground is depicted with a current detector comprising the current-sense amplifier and the shunt resistor 130, other current detectors are contemplated for other applications including hall based current detectors, or anisotropic magneto resistance current detectors. Current detectors are electrical components with a structure allowing current to flow while capturing a measurement and other types of current detectors can be used without departing from the scope of the hybrid current sense system 100.

A second current-sense amplifier 140 can be coupled across the S2 for measuring a voltage drop across the S2. The positive current sensing input 132 of the second current-sense amplifier 140 can be coupled to the drain 110 of the S2 and the negative current sensing input 134 of the second current-sense amplifier 140 can be coupled to the source 112 of the S2.

A third current-sense amplifier 142 can be coupled across the S4 for measuring a voltage drop across the S4. The positive current sensing input 132 of the third current-sense amplifier 142 can be coupled to the drain 110 of the S4 and the negative current sensing input 134 of the third current-sense amplifier 142 can be coupled to the source 112 of the S4.

A fourth current-sense amplifier 144 can be coupled across the S6 for measuring a voltage drop across the S6. The positive current sensing input 132 of the fourth current-sense amplifier 144 can be coupled to the drain 110 of the S6 and the negative current sensing input 134 of the fourth current-sense amplifier 144 can be coupled to the source 112 of the S6.

The second current-sense amplifier 140, the third current-sense amplifier 142, and the fourth current-sense amplifier 144 can be any amplifier including a voltage amplifier or an operational amplifier, and are disclosed as current-sense amplifiers for clarity only. The second current-sense amplifier 140, the third current-sense amplifier 142, and the fourth current-sense amplifier 144 are to be understood herein as current detectors.

The voltage outputs 136 for each of the current-sense amplifiers can be coupled to an analog-to-digital converter. For example, the voltage output 136 of the first current-sense amplifier 138 can be coupled to a first analog-to-digital converter 152. The first analog-to-digital converter 152 can have a calibration voltage trigger 154.

The calibration voltage trigger 154 can be a time trigger for the first analog-to-digital converter 152 to read the first current-sense amplifier 138. The calibration voltage trigger 154 can be in the middle of T1 of FIG. 3. Alternatively, it is contemplated that the calibration voltage trigger 154 could be in the middle of T2 of FIG. 3.

The voltage output 136 of the second current-sense amplifier 140 can be coupled to a second analog-to-digital converter 156 in a U-phase detection layer 158. The second analog-to-digital converter 156 can have a U-phase voltage trigger 160. The U-phase voltage trigger 160 can be set to trigger at the middle of T3 as shown in FIG. 3.

The voltage output 136 of the third current-sense amplifier 142 can be coupled to a third analog-to-digital converter in a V-phase detection layer 166 and the voltage output 136 of the fourth current-sense amplifier 144 can be coupled to a fourth analog-to-digital converter in a W-phase detection layer 168, which are depicted with broken arrows. It is contemplated that the V-phase voltage trigger for the third analog-to-digital converter and the W-phase voltage trigger of the fourth analog-to-digital converter could also be mid T3.

The analog-to-digital converters can have digital outputs 170 which provide current information to the controller 102. It is to be understood that the controller 102 as the current calibrator has intrinsic structural elements in that it must be communicatively coupled to the current-sense amplifiers with communication lines. The digital outputs 170 of the U-phase detection layer 158, the V-phase detection layer 166, and the W-phase detection layer 168 can be input into the controller 102 as current information. The controller 102 can be a current calibrator to calibrate the current information using the digital output 170 of the first analog-to-digital converter 152.

The controller 102 can be a processor or include logic gates for processing the digital outputs 170. The controller 102 can also have circuitry for calculating position and speed using advanced control methods. Alternatively, a remote processor could be used with the advanced control methods when they are too resource heavy for the controller 102.

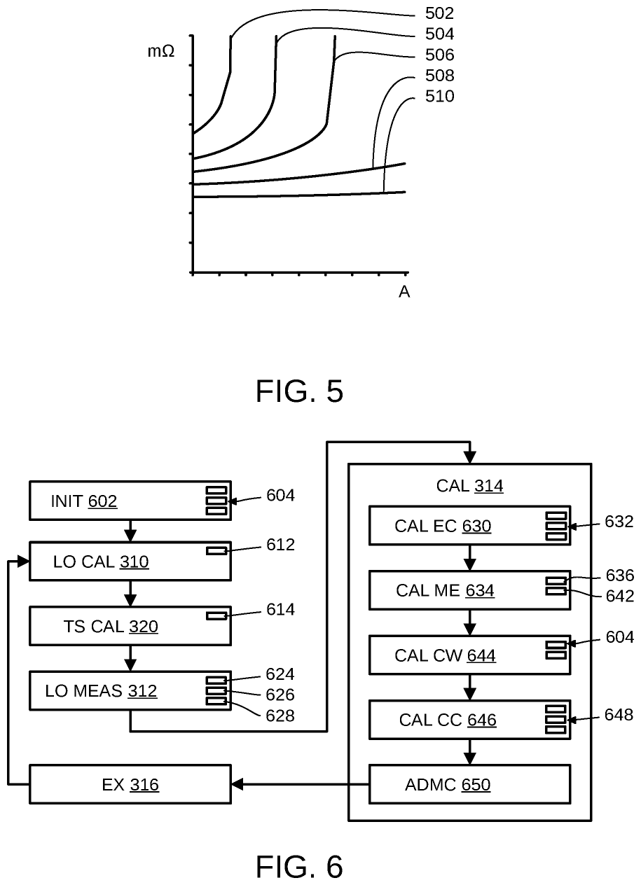

It has been discovered that when only one low-side switch is active during the measurement of the first current-sense amplifier 138, that measurement can be used to calibrate the active switch. This is, for example, as depicted in FIG. 3, S6 is the single active low-side switch in T1 and the sampling of the first current-sense amplifier 138 can be used to calibrate the reading of the fourth current-sense amplifier 144 for the temperature variance of S6 as shown in FIG. 4 and for the on-state resistance (RON) of S6 as shown in FIG. 5.

It has been discovered that the shunt resistor 130 and the first current-sense amplifier 138 can provide a very accurate reading during the pulse-width modulated signal cycle. Since only a single reading is required during a complete cycle, the first current-sense amplifier 138 and the first analog-to-digital converter 152 can be manufactured to lower requirements. That is, slower and cheaper designs can be used for the first current-sense amplifier 138 and the first analog-to-digital converter 152.

Similarly, it has been discovered that the hybrid current sense system 100 enables the second current-sense amplifier 140, the third current-sense amplifier 142, and the fourth current-sense amplifier 144 and their associated analog-to-digital converters, to only sample once during each pulse-width modulated signal cycle. This again allows the use of slower and cheaper design.

As an illustrative example, a three-phase brushless direct current motor with eight poles operating at 8000 revolutions per minute would need a drive signal of one kilohertz. Pulse-width modulated signal frequency is normally at least twenty-four times higher than sinusoidal frequency. With the hybrid current sense system 100 only requiring a single sample during the pulse-width modulated signal cycle, each of the analog-to-digital converters and current-sense amplifiers could run at twenty-four kilohertz.

The hybrid current sense system 100 can provide cost reduction over a triple shunt solution with the elimination of two shunts, which further shrinks the footprint and increases efficiency with fewer losses on the sensor resistors. The hybrid current sense system 100 also provides an easier layout, enables using power modules without an individual return to ground, and is less sensitive to phase-shunt sensing mismatch due to printed circuit board layout asymmetries.

For expository purposes, the high-side switches can pull the output of their phase high when they are activated with a high pulse-width modulated signal and when the low-side switches are activated they can pull the output of their phase toward ground and in this way convert the pulse-width modulated signals into the three-phase sinusoidal drive signal 202.

For example, the S1 can be activated to pull the U-output 116 towards the source voltage 126 while the S2 can be activated to pull the U-output 116 toward ground 128. Illustratively, the pulse-width modulated signals can occur at least twenty-four times per cycle of the U-phase portion of the three-phase sinusoidal drive signal 202.

Referring now to FIG. 2, therein is shown a graphical depiction of a three-phase sinusoidal drive signal 202. The three-phase sinusoidal drive signal 202 can for example be the output of the three-phase inverter 106 of FIG. 1.

Each phase of the three-phase sinusoidal drive signal 202 can be a drive input into a single phase of a three-phase electric motor. The three-phase sinusoidal drive signal 202 is set forth with time along a horizontal axis and voltage along a vertical axis.

The sinusoidal drive signal is beneficial with most available motors when compared with other signals and is therefore used as an illustrative, non-limiting example. The controller 102 of FIG. 1 can provide pulse-width modulated signals to each switch of the three-phase inverter 106 and each phase generates one phase of the three-phase sinusoidal drive signal 202.

That is, the U-phase 114 of FIG. 1 can generate a U-phase 204, the V-phase 118 of FIG. 1 can generate a V-phase 206, and the W-phase 122 of FIG. 1 can generate a W-phase 208.

The three-phase sinusoidal drive signal 202 is shown over a single electrical cycle having six sectors labeled I-VI. Each of the six sectors is driven by at least four pulse-width modulated signal cycles, the present example is based off of eight pulse-width modulated signal cycles per sector.

Each sector is sixty degrees phase shifted. A single phase is shown to have a “saddle-like” shaped to permit full use of the supply while peak-to-peak voltages and currents are sinusoidal.

Referring now to FIG. 3, therein is shown a timing diagram for a single pulse-width modulated signal cycle 302 of the low-side switches of FIG. 1 at time 3-3 of FIG. 2. The pulse-width modulated signal cycle 302 can provide an S2 pulse-width modulated signal 304 driving S2 of FIG. 1, an S4 pulse-width modulated signal 306 driving S4 of FIG. 1, and an S6 pulse-width modulated signal 308 driving S6 of FIG. 1. The pulse-width modulated signal cycle 302 is set forth with time along a horizontal axis and voltage along a vertical axis.

The high-side switches of FIG. 1 are not shown and are driven by pulse-width modulated signals that are an inverse of the low-side switch on the same phase. For ease of description, this switching pattern is set forth but is not intended to limit the scope of the hybrid current sense system 100. The single pulse-width modulated signal cycle 302 can be divided into states T0, T1, T2, and T3.

At T0 all the low-side switches S2, S4, and S6 are off. At T1 switch S6 is active, at T2 switches S6 and S4 are active, and at T3 all low-side switches are active. It has been discovered that when only a single low-side switch is active, a current through that switch can be calculated with a voltage measured at T1 with the first current-sense amplifier 138 of FIG. 1 divided by the known value of the shunt resistor 130 of FIG. 1.

At T1, the current through only a single active low-side switches will be measured with the shunt resistor 130. This is to be understood as the “single active low-side switch” for the single pulse-width modulated signal cycle 302. Here the single active low-side switch would be S6.

Only a single measurement at T1 over the pulse-width modulated signal cycle is not adequate for utilizing advanced control methods, but has been discovered to be an excellent calibration measurement for non-linear voltage of the single active low-side switch. Here, the hybrid current sense system 100 of FIG. 1 is shown having a low-side calibration measurement 310 in the middle of T1, which, in sector I of the electric cycle of FIG. 2, corresponds to a measurement of current through S6.

T1 will correspond to each of the low-side switches S2, S4, and S6 being a single active low-side switch at least once during each electrical cycle. Each electrical cycle should have at least twenty four pulse-width modulated signal cycles but in the present example of FIG. 2 includes forty-eight pulse-width modulated signal cycles.

The hybrid current sense system 100 can execute a low-side switch measurement 312 in the middle of T3, which corresponds to S2, S4, and S6 all being active. The low-side switch measurement 312 can read the voltage across S2 with the second current-sense amplifier 140 of FIG. 1, across S4 with the third current-sense amplifier 142 of FIG. 1, and across S6 with the fourth current-sense amplifier 144 of FIG. 1, these readings should be understood herein as current information.

The measurement of the voltage across S2, S4, and S6 can be done in parallel at the low-side switch measurement 312. The outputs of the current-sense amplifiers can be converted to a digital signal with analog-to-digital converters.

It will be appreciated that the voltage measured at the low-side switch measurement 312 can be used as inputs for advanced control methods such as sensorless field-oriented control or direct torque control. The current read at the low-side switch measurement 312, however is subject to the temperature non-linearities of FIG. 4 and the RON current non-linearities of FIG. 5.

After the low-side switch measurement 312, the hybrid current sense system 100 can execute a calculation step 314 for the remaining duration of the single pulse-width modulated signal cycle 302. During the calculation step 314 the current information can be calibrated. In one contemplated method, calibrating the current information can include calculating a calibration weight for the single active low-side switch of T1.

The calibration calculation can begin by determining the measured current through the single active low-side switch measured during the low-side calibration measurement 310. Next the measured current can be compared with an estimated current.

The estimated current is calculated based on the voltage measured across the single active low-side switch during the low-side switch measurement 312. It should be noted that during the low-side switch measurement 312 at T3, all low-side switches are active and the reference to the single active low-side switch only refers to the switch that was active during T1.

The measured current is compared with the estimated current, the difference being a calibration weight. The estimated current plus the calibration weight can be the calibrated current. The two switches that are not calibrated during the pulse-width modulated signal cycle will utilize a calibration weight from a previous cycle.

Thus, the calibrated currents for each of the low-side switches will be updated approximately once every third pulse-width modulated signal cycle, although there are methods of increasing the number of switches to two per pulse-width modulated signal cycle.

The calibrated current for each of the switches can be used as inputs to advanced control methods. Position control and speed control from these advanced control methods can be calculated for each phase, or leg, based on the calibrated current for each switch using sensorless field-oriented control, for example.

In addition to calculating the calibrated current, the resistance of the single active low-side switch can be calculated by dividing the voltage measured across the single active low-side switch during T3 with the low-side switch measurement 312 by the current calculated for the single active low-side switch using the measurement during T1 with the low-side calibration measurement 310. The resistance can be correlated with temperature of the single active low-side switch using the relationship shown, for example, in FIG. 4.

The resistance of the single active low-side switch can also be correlated to current with the RON relationship shown, for example, in FIG. 5. It has been discovered that the resistance can be monitored for each of the switches and any over temperatures can be detected with over temperature thresholds and reported or can be used to generate a fault code.

The hybrid current sense system 100 can perform an execution step 316 at the beginning of the single pulse-width modulated signal cycle 302 at TO. During the execution step 316 the controller 102 of FIG. 1 can shift the pulse-width modulated signals for each of the six switches for position and speed based on the calibrated current information determined during the previous pulse-width modulated signal cycle. Further, during the execution step 316 the controller 102 can update the calibration weight for the single active low-side switch of the previous pulse-width modulated signal cycle.

It is contemplated that the hybrid current sense system 100 could also take further calibration measurements during the pulse-width modulated signal cycle. Illustratively, for example, the hybrid current sense system 100 could also measure the current through the shunt resistor 130 during a two switch calibration measurement 320.

The two switch calibration measurement 320 can be performed during T2 and can provide an additional current measurement for a second determinable low-side switch. The current measured through the shunt resistor 130 at T2 can be the current of the W-output 124 of FIG. 1 or IW of FIG. 1 as the S5 of FIG. 1 for the W-output 124 would be active. The IW can be used to calculate the current through S6 using Kirchhoff's law, which states:

IW=−(IU+IV) Equation 1

That is, the current measured in T2 with the first current-sense amplifier 138 can be used to calibrate the low-side switch current measurement on S6 using the fourth current-sense amplifier 144, which is performed during T3 and measures −IW. The two switch calibration measurement 320 can increase the number of switches from one switch being calibrated every pulse-width modulated signal cycle to two switches.

While the hybrid current sense system 100 has been described with regard to the controller 102 calibrating the current information with current weights and providing a calibrated current, the hybrid current sense system 100 can be implemented with other methods as well. Other methods of calibrating current information can include the use of analog-to-digital converters as current calibrators for calibrating current information from the low-side switches, and after which, the calculations for using calibrated current information within the advanced control methods is accomplished in software or hardware.

Further methods could also include calculating a calibration error, which could be the difference between a previous calibration weight and a new calibration weight, and which can then be used to calibrate the current information by tuning a current-sense amplifier gain based on the calibration error, for example. The current calibrator for calculating the calibration error could be an amplifier or the controller 102.

Yet further methods could include calibrating the current information for both the low-side switches and the high-side switches in digital, for example in the controller 102, or in analog, for example using a digital-to-analog converter or error amplifiers. The controller 102, digital-to-analog converter, error amplifiers, or a combination thereof can therefore be used as the current calibrator.

It has been discovered that these methods have increased importance because they can each advantageously utilize the calibration readings of the shunt resistor 130 in combination with less uncalibrated current information across the switches to calibrate the current information which can be used with advanced control methods of three-phase motors.

Referring now to FIG. 4, therein is shown a graphical view of drain to source active state resistance with respect to temperature for one of the switches of FIG. 1. The relationship is set forth with the pre-selected values of fifty amps through the switch and ten volts across the gate and source of the switch.

The vertical axis can set forth resistance measured in 1 milli-ohms per division, starting at zero ohms. The horizontal axis can set forth temperature in forty degrees Celsius increments starting at negative sixty degrees.

A first trace can be an illustration of a typical trace 402 showing a typical relationship between resistance and temperature for one of the switches. A second trace can be an illustration of a maximum trace 404 showing a maximum relationship between resistance and temperature for one of the switches.

It has been discovered that the temperature of the switches can be estimated once the resistance is computed, for example during the calculation step 314 of FIG. 3. Temperatures can be monitored for inconsistencies or trigger alarms if the temperature rises above a temperature threshold.

Referring now to FIG. 5, therein is shown a graphical view of the drain to source active state resistance with respect to current for one of the switches of FIG. 1. The relationship is set forth with the pre-selected values of twenty five degrees Celsius for running temperature of the switch.

The hybrid current sense system 100 can compensate not only for the temperature of the switch but also for the RON current variance. In particular the RON of power FETs can vary significantly from lot to lot. The actual RON value could differ from the nominal RON value. The hybrid current sense system 100 compensates this error by calibrating with respect to a precise shunt resistor (or other accurate sense element).

The vertical axis can set forth resistance measured in 1 milli-ohms per division, starting at zero ohms. The horizontal axis can set forth current in fifty amp increments starting at zero amps.

The relationship can be set forth with a five volt trace 502, a five and a half volt trace 504, a six volt trace 506, a seven volt trace 508, and a ten volt trace 510. Particularly, the current detected through the shunt resistor 130 of FIG. 1 during the low-side calibration measurement 310 of FIG. 3 in the middle of T1 is the current of the single active low-side switch and can be compared with an estimated current of the single active low-side switch based on the voltage measurement during T3 of the low-side switch measurement 312 of FIG. 3. The difference can be a calibration weight for the single active low-side switch. The traces set forth the relationship between current and resistance and depend on the voltage across the switch and the temperature of the switch.

Referring now to FIG. 6, therein is shown a control flow for operating the hybrid current sense system 100 of FIG. 1. The hybrid current sense system 100 can begin by executing an initialization step 602. During the initialization step 602 calibration weights 604 can be initialized for each of the switches. Continuing with the example of FIG. 1, three calibration weights can be initialized, one for the U-phase 114, one for the V-phase 118, and one for the W-phase 122 each of FIG. 1.

The operation of the hybrid current sense system 100 will be described with regard to the timing states of FIG. 3 for descriptive purposes, but should not be thereby limited. After the initialization step 602, the hybrid current sense system 100 can execute the low-side calibration measurement 310 at the middle of T1 of FIG. 3. During the low-side calibration measurement 310 a single active low-side switch voltage 612 can be measured across the shunt resistor 130 of FIG. 1 with the first current-sense amplifier 138 of FIG. 1.

After the low-side calibration measurement 310 the hybrid current sense system 100 can execute the two switch calibration measurement 320 at the middle of T2 of FIG. 3. During the two switch calibration measurement 320 the current measured through the shunt resistor 130 at T2 can be the current of the W-output 124 of FIG. 1 or IW of FIG. 1 as the S5 of FIG. 1 for the W-output 124 would be active. The IW can be used to calculate the current through S6 of FIG. 1 using Kirchhoff's law of Equation 1.

The hybrid current sense system 100 can next execute the low-side switch measurement 312 at the middle of T3 of FIG. 3. During the low-side switch measurement 312 the voltages across each of the low-side switches are measured including an S2 voltage 624, an S4 voltage 626, and an S6 voltage 628.

After the middle of T3 and during the second half of the pulse-width modulated signal cycle the hybrid current sense system 100 can perform the calculation step 314. The calculation step 314 can include many smaller calculations.

Illustratively, for example, the calculation step 314 can include a calculate estimated current step 630. During the calculate estimated current step 630 the voltages measured during the low-side switch measurement 312 can be used to calculate estimated currents 632 for each of the three low-side switches by dividing voltages measured during the low-side switch measurement 312 by an average resistance or a known resistance.

Furthermore, during the calculation step 314, the hybrid current sense system 100 can execute a calculate measured current step 634. During the calculate measured current step 634, the single active low-side switch voltage 612 can be divided by the value of the shunt resistor 130 to yield a single active low-side switch measured current 636.

One additional measured current can be calculated. Illustratively, when the two switch calibration measurement 320 is made during T2, the current measured through the shunt resistor 130 at T2 can be the current of the W-output 124, or IW, as the S5 for the W-output 124 is active at T2. The IW can be used to calculate the current through S6 of FIG. 1 using Kirchhoff's law of Equation 1.

The current through the second determinable low-side switch can be a Kirchhoff derived current from the two switch calibration measurement 320 at T2, or a low-side switch derived current 642.

Once the calculate measured current step 634 is complete, the hybrid current sense system 100 can execute a calculate calibration weights step 644. The calculate calibration weights step 644 can compare the measured currents determined in the calculate measured current step 634 with the estimated currents 632 determined in the calculate estimated current step 630.

More particularly, the difference between the single active low-side switch measured current 636 and the estimated current 632 for that switch can be the calibration weight 604 for that switch. Similarly, the differences between the low-side switch derived current 642 can be compared with the estimated current 632 for the respective switch. In the case of FIG. 3, the respective switch would be S6.

The calibration weights 604 for the three switches can be updated. Once the calculate calibration weights step 644 has been completed, the hybrid current sense system 100 can execute a calculate calibrated current step 646.

The calculate calibrated current step 646 can sum the estimated current 632 for each switch with the calibration weight 604 for each switch to produce a calibrated current 648 for each switch. It is to be noted that when a calibration weight 604 is not calculated for each switch, a previous or initial calibration weight 604 can be summed with the estimated current 632 to determine the calibrated current 648.

It has been discovered that utilizing the estimated currents 632 allows for every switch on the low-side to be measured at each pulse-width modulated signal cycle, which provides excellent information input into advanced control methods. The calibration of one or two switches per pulse-width modulated signal cycle increases the accuracy of the advanced control method.

Once the calibrated currents 648 have been determined, the calibrated currents 648 can be used as inputs into an advanced control methods step 650. During the advanced control methods step 650, the calibrated current 648 for each of the switches can be used as inputs to advanced control methods such as sensorless field-oriented control and direct torque control. Position control and speed control from these advanced control methods can be calculated for each phase, or leg, based on the calibrated current 648 for each switch.

Once the calculation step 314 has been performed, the hybrid current sense system 100 can execute the execution step 316. During the execution step 316 the controller 102 of FIG. 1 can shift the pulse-width modulated signals for each of the six switches for position and speed control based on the calibrated currents 648 determined during the previous pulse-width modulated signal cycle. Further, during the execution step 316 the controller 102 can update the calibration weights 604 for the single active low-side switch and the second determinable low-side switch of the previous pulse-width modulated signal cycle.

The execution step 316 can be performed at the beginning of TO. Both the calculation step 314 and the execution step 316 can be performed by a processor in the controller 102. Alternatively, some of the more complex calculations can be performed by a remote processor in communication with the controller 102.

It is contemplated that the calculation step 314 can further include a calculate temperature value for each of the switches determined in the calculate measured current step 634. The temperature value can be the voltages, measured during the low-side switch measurement 312, divided by a corresponding one of the measured currents determined in calculate measured current step 634. That is, for example, the S6 voltage 628 could be divided by the single active low-side switch measured current 636 to find the resistance of S6, which corresponds to temperature as set forth in FIG. 4.

The resistance for each of the switches can be determined once the current is measured with the first current-sense amplifier 138 for the respective switch. A resistance threshold can be used to generate a fault if the resistance of the switch exceeds the resistance threshold.

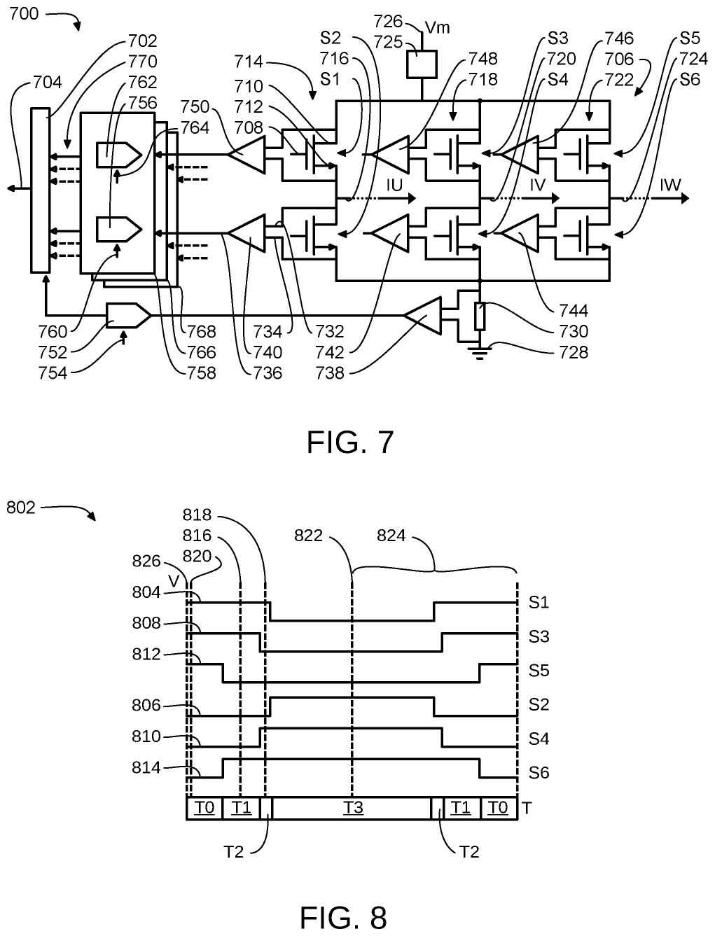

Referring now to FIG. 7, therein is shown a schematic view of the hybrid current sense system 700 in a second embodiment. The hybrid current sense system 700 is described with reference to a power stage of a brushless three-phase motor driver for illustrative purposes only and could be adapted to other applications that utilize pulse-width modulated inverters such as those used with solenoids, for example.

The power stage is shown including a controller 702 for generating pulse-width modulated signals on a controller output 704 connected to switches within a three-phase inverter 706. The pulse-width modulated signals can, for example, be the pulse-width modulated signals to the low-side switches shown in FIG. 3 but also include pulse-width modulated signals for the high-side switches.

The pulse-width modulated signals drive switches within the three-phase inverter 706 and generate the three-phase sinusoidal drive signal 202 of FIG. 2. The three-phase sinusoidal drive signal is the drive signal 202, for example, generated to drive a three-phase brushless direct current motor (not shown).

More particularly, the switches within the three-phase inverter 706 can be transistors and are specifically depicted as NPN doped junction field effect transistors each having a gate 708, a drain 710, and a source 712. Although the transistors are depicted as NPN FETs, the hybrid current sense system 100 can apply regardless the type of switches in use.

The switches illustratively can be NFETs, complementary PFET+NFETs, eGaN FETs, or other switches. The controller output 704 can be individual connections from the controller 702 to the gate 708 for each switch within the three-phase inverter 706.

The three-phase inverter 706 can include six switches arranged into three phases, each having two switches. That is, the three-phase inverter 706 is shown having: a U-phase 714 with a U-output 716 and switches S1 and S2; a V-phase 718 with a V-output 720 and switches S3 and S4; and a W-phase 722 with a W-output 724 and switches S5 and S6.

The U-output 716, the V-output 720, and the W-output 724 are phase outputs and are described with reference to standardized terminal markings and direction of rotation for positive electrical phase sequence U-V-W of three-phase electrical motors. Each of the phase outputs, including the U-output 716, the V-output 720, and the W-output 724, can be an input for one phase or winding of a three-phase brushless direct current motor.

In greater detail, S1, S3, and S5 can be considered high-side switches having their drains 710 coupled through a high-side current detector 725 to a high voltage rail such as a source voltage 726. The source voltage 726 can be a positive DC voltage or Vm, which is the max voltage of the three-phase sinusoidal drive signal 202. The high-side current detector 725 is depicted as a generic component block, which in representative form, shows a current-sense amplifier connected across a shunt resistor, a hall based current detector, or anisotropic magneto resistance current detector.

The U-output 716 is shown coupled to both the source 712 of S1 and the drain 710 of S2. The V-output 720 is shown coupled to both the source 712 of S3 and the drain 710 of S4. The W-output 724 is shown coupled to both the source 712 of S5 and the drain 710 of S6.

S2, S4, and S6 can be considered low-side switches having their sources 712 coupled to a low voltage rail such as ground 728 through the low-side current detector. The high voltage rail and the low voltage rail are described for clarity as the source voltage 726 and the ground 728, respectively. It is to be understood that the source voltage 726 can be any high voltage rail having a voltage higher than the low voltage rail while the ground 728 can be any low voltage rail with a voltage lower than the high voltage rail.

Voltage drops across the low-side switches, the high-side switches, and the shunt resistor 730 can be detected and monitored by current-sense amplifiers, each having a positive current sensing input 732, a negative current sensing input 734, and a voltage output 736. The current-sense amplifier can be optimized for monitoring current of inductive loads, such as DC motors and solenoids, where common-mode voltages can become negative due to inductive kickback, reverse-battery conditions, or transient events.

Illustratively, for example, a first current-sense amplifier 738 can be coupled across the shunt resistor 730 for measuring a voltage drop across the shunt resistor 730 which is proportional to the current through the shunt resistor 730. Current through the shunt resistor 730 can be calculated and determined by dividing the measured voltage by the known value of the shunt resistor 730.

The positive current sensing input 732 of the first current-sense amplifier 738 can be coupled between the sources 712 of S2, S4, and S6 and the shunt resistor 730. The negative current sensing input 734 of the first current-sense amplifier 738 can be coupled between the shunt resistor 730 and ground 728.

While the current reading between the switches of the three-phase inverter 706 and ground is depicted with the low-side current detector comprising the first current-sense amplifier 738 and the shunt resistor 730, other current detectors are contemplated for other applications including hall based current detectors, or anisotropic magneto resistance current detectors. Current detectors are electrical components with a structure allowing current to flow while capturing a measurement and other types of current detectors can be used without departing from the scope of the hybrid current sense system 700.

A second current-sense amplifier 740 can be coupled across the S2 for measuring a voltage drop across the S2. The positive current sensing input 732 of the second current-sense amplifier 740 can be coupled to the drain 710 of the S2, and the negative current sensing input 734 of the second current-sense amplifier 740 can be coupled to the source 712 of the S2.

A third current-sense amplifier 742 can be coupled across the S4 for measuring a voltage drop across the S4. The positive current sensing input 732 of the third current-sense amplifier 742 can be coupled to the drain 710 of the S4, and the negative current sensing input 734 of the third current-sense amplifier 742 can be coupled to the source 712 of the S4.

A fourth current-sense amplifier 744 can be coupled across the S6 for measuring a voltage drop across the S6. The positive current sensing input 732 of the fourth current-sense amplifier 744 can be coupled to the drain 710 of the S6, and the negative current sensing input 734 of the fourth current-sense amplifier 744 can be coupled to the source 712 of the S6.

A fifth current-sense amplifier 746 can be coupled across the S5 for measuring a voltage drop across the S5. The positive current sensing input 732 of the fifth current-sense amplifier 746 can be coupled to the drain 710 of the S5, and the negative current sensing input 734 of the fifth current-sense amplifier 746 can be coupled to the source 712 of the S5.

A sixth current-sense amplifier 748 can be coupled across the S3 for measuring a voltage drop across the S3. The positive current sensing input 732 of the sixth current-sense amplifier 748 can be coupled to the drain 710 of the S3, and the negative current sensing input 734 of the sixth current-sense amplifier 748 can be coupled to the source 712 of the S3.

A seventh current-sense amplifier 750 can be coupled across the S1 for measuring a voltage drop across the S1. The positive current sensing input 732 of the seventh current-sense amplifier 750 can be coupled to the drain 710 of the S1, and the negative current sensing input 734 of the seventh current-sense amplifier 750 can be coupled to the source 712 of the S1.

The second current-sense amplifier 740, the third current-sense amplifier 742, the fourth current-sense amplifier 744, the fifth current-sense amplifier 746, the sixth current-sense amplifier 748, and the seventh current-sense amplifier 750 can be any amplifier including a voltage amplifier or an operational amplifier, and are disclosed as current-sense amplifiers for clarity only. The second current-sense amplifier 740, the third current-sense amplifier 742, the fourth current-sense amplifier 744, the fifth current-sense amplifier 746, the sixth current-sense amplifier 748, and the seventh current-sense amplifier 750 are to be understood herein as current detectors.

The voltage outputs 736 for each of the current-sense amplifiers can be coupled to an analog-to-digital converter. For example, the voltage output 736 of the first current-sense amplifier 738 can be coupled to a first analog-to-digital converter 752. The first analog-to-digital converter 752 can have a calibration voltage trigger 754.

The calibration voltage trigger 754 can be a time trigger for the first analog-to-digital converter 752 to read the first current-sense amplifier 738. The calibration voltage trigger 754 can be in the middle of T1 of FIG. 3. Alternatively, it is contemplated that the calibration voltage trigger 754 could be in the middle of T2 of FIG. 3.

The high-side current detector 725 could similarly be coupled to the controller 702 with an analog-to-digital converter having a calibration voltage trigger. It has been discovered that a measured current can be determined for the switches using either the high-side current detector 725 or a low-side current detector comprising the first current-sense amplifier 738 and the shunt resistor 730 interchangeably.

That is, the measured current can be determined for each of the phases either through the high-side current detector 725 or through the low-side current detector using identical methods, and all methods disclosed herein with regard to measuring current with the low-side current detector can be used with the high-side current detector. Functionally either the high-side current detector or the low-side current detector can be used to determine the measured current, and both can be triggered at the same times for reading the same phases of the three-phase sinusoidal drive signal 202.

The voltage output 736 of the second current-sense amplifier 740 can be coupled to a low-side U-phase analog-to-digital converter 756 in a U-phase detection layer 758. The low-side U-phase analog-to-digital converter 756 can have a low-side U-phase voltage trigger 760. The low-side U-phase voltage trigger 760 can be set to trigger at the middle of T3 as shown in FIG. 3.

The voltage output 736 of the seventh current-sense amplifier 750 can be coupled to a high-side U-phase analog-to-digital converter 762 in the U-phase detection layer 758. The high-side U-phase analog-to-digital converter 762 can have a high-side U-phase voltage trigger 764. The high-side U-phase voltage trigger 764 can be set to trigger at the middle of T0, at which time all high-side switches are turned on.

The voltage output 736 of the third current-sense amplifier 742 can be coupled to a low-side V-phase analog-to-digital converter in a V-phase detection layer 766. The voltage output 736 of the sixth current-sense amplifier 748 can be coupled to a high-side V-phase analog-to-digital converter in the V-phase detection layer 766.

The voltage output 736 of the fourth current-sense amplifier 744 can be coupled to a low-side W-phase analog-to-digital converter in a W-phase detection layer 768. The voltage output 736 of the fifth current-sense amplifier 746 can be coupled to a high-side W-phase analog-to-digital converter in the W-phase detection layer 768.

The connections between the voltage outputs 736 of the third current-sense amplifier 742 to the low-side V-phase analog-to-digital converter, between the voltage outputs 736 of the fourth current-sense amplifier 744 to the low-side W-phase, between the voltage outputs 736 of the fifth current-sense amplifier 746 to the high-side W-phase analog-to-digital converter, and between the voltage outputs 736 of the sixth current-sense amplifier 748 to the high-side V-phase analog-to-digital converter are depicted with broken arrows.

It is contemplated that the low-side V-phase voltage trigger for the low-side V-phase analog-to-digital converter and the low-side W-phase voltage trigger of the low-side W-phase analog-to-digital converter could also be mid T3. It is further contemplated that the high-side V-phase voltage trigger for the high-side V-phase analog-to-digital converter and the high-side W-phase voltage trigger of the high-side W-phase analog-to-digital converter could be mid TO.

It is contemplated that an alternative topology to the high-side and low-side analog-to-digital converters could be a single analog-to-digital converter for each phase used together with a multiplexer. In this alternative topology, fewer components might be used.

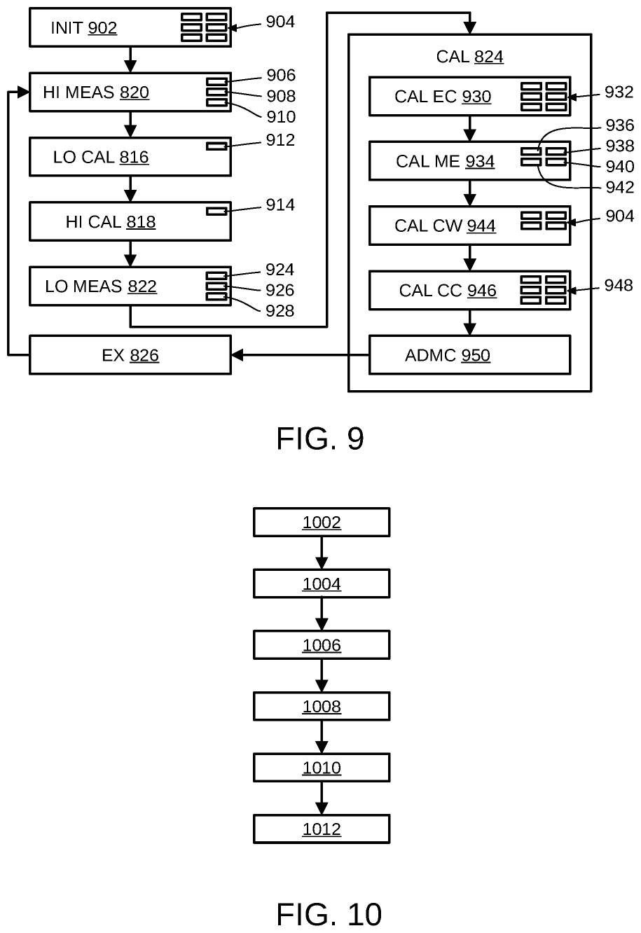

The analog-to-digital converters can have digital outputs 770. The digital outputs 770 of the U-phase detection layer 758, the V-phase detection layer 766, and the W-phase detection layer 768 can be input into the controller 702 as current information. The controller 702 can be a current calibrator to calibrate the current information using the digital output 770 of the first analog-to-digital converter 752 as described with regard to the calculation step 824 of FIGS. 8 and 9.

The controller 702 can be a processor or include logic gates for processing the digital outputs 770. The controller 702 can also have circuitry for calculating position and speed using advanced control methods. Alternatively, a remote processor could be used with the advanced control methods when they are too resource heavy for the controller 702.

It has been discovered that when only one low-side switch or high-side switch is active during the measurement across the shunt resistor 730, that measurement can be used to calibrate the corresponding active switch. This is, for example, depicted in FIG. 8, S1 is the only high-side switch active in T2 and the sampling of the first current-sense amplifier 738 can be used to calibrate the reading of the seventh current-sense amplifier 750 for the temperature variance of S1 as shown in FIG. 4 and for the RON of S1 as shown in FIG. 5.

It has been discovered that the low-side current detector comprising the shunt resistor 730 and the first current-sense amplifier 738 or the high-side current detector 725 can provide a very accurate reading during the pulse-width modulated signal cycle. Since only a single reading is required during a complete cycle, the first current-sense amplifier 738 and the first analog-to-digital converter 752 can be manufactured to lower requirements. That is, slower and cheaper designs can be used for the first current-sense amplifier 738, the first analog-to-digital converter 752, and components of the high-side current detector 725.

Similarly, it has been discovered that the hybrid current sense system 700 enables the second current-sense amplifier 740, the third current-sense amplifier 742, and the fourth current-sense amplifier 744 and their associated analog-to-digital converters, to only sample once during each pulse-width modulated signal cycle. This again allows the use of slower and cheaper design.

As an illustrative example, a three-phase brushless direct current motor with eight poles operating at 8000 revolutions per minute would need a drive signal of one kilohertz. Pulse-width modulated signal frequency is normally at least twenty-four times higher than sinusoidal frequency. With the hybrid current sense system 700 only requiring a single sample during the pulse-width modulated signal cycle, each of the analog-to-digital converters and current-sense amplifiers could run at twenty-four kilohertz.

As such, the hybrid current sense system 700 can eliminate sampling window constraints because both T0 and T3 are wide enough for sampling. Furthermore, the advanced control methods such as sensorless field-oriented control and direct torque control can be used because the voltage across all high-side switches during T0 and all low-side switches during T3 are obtained.

It has been discovered that the voltage measurements across the high-side switches and the low-side switches together with an estimate of the current based on the measured voltage is enough to enable and use the advanced control methods. The relationship between the measured voltages to the actual currents will vary due to the relationships set forth in FIGS. 4 and 5, but this can be compensated for.

An additional benefit of the second embodiment of FIG. 8 compared with the first embodiment of FIG. 1 is that the three-phase current information can be acquired twice per electrical cycle (mid of T0 and mid of T3) which doubles the theoretical bandwidth of the current control loop. The calibration can be done in the middle of T3 for the low-side switches and in the middle of T0 for the high-side switches.

As a further benefit to the hybrid current sense system 700, the resistance of the switches together with their temperature can be monitored for deviations or conditions above a preset warning or replacement threshold.

Referring now to FIG. 8, therein is shown a timing diagram for a single pulse-width modulated signal cycle 802 for both the high-side switches and the low-side switches of FIG. 7. The pulse-width modulated signal cycle 802 can provide: an S1 pulse-width modulated signal 804 driving S1 of FIG. 7, an S2 pulse-width modulated signal 806 driving S2 of FIG. 7, an S3 pulse-width modulated signal 808 driving S3 of FIG. 7, an S4 pulse-width modulated signal 810 driving S4 of FIG. 7, an S5 pulse-width modulated signal 812 driving S5 of FIG. 7, and an S6 pulse-width modulated signal 814 driving S6 of FIG. 7. The pulse-width modulated signal cycle 802 is set forth with time along a horizontal axis and voltage along a vertical axis.

The S1 pulse-width modulated signal 804, the S3 pulse-width modulated signal 808, and the S5 pulse-width modulated signal 812 represent the high-side switches and are presented, as is typically the case, as inverted to the S2 pulse-width modulated signal 806, the S4 pulse-width modulated signal 810, and the S6 pulse-width modulated signal 814 representing the low-side switches. For ease of description, this switching pattern is set forth but is not intended to limit the scope of the hybrid current sense system 700.

The single pulse-width modulated signal cycle 802 can be divided into states T0, T1, T2, and T3. At T0 all the low-side switches S2, S4, and S6 are inactive while all high-side switches S1, S3, and S5 are active. At T1 switch S6 is active while S5 is inactive. At T2 switches S6 and S4 are active while S5 and S3 are inactive. At T3 all low-side switches are active while all high-side switches are inactive.

It has been discovered that during T1 when only one low-side switch is active and during T2 when only one high-side switch is active, a current through that active corresponding switch can be calculated with a voltage measurement across the shunt resistor 730 of FIG. 7. Current detection and measurement at T1 for one of the low-side switches can be completed based on the low-side current detector comprising a voltage measured at T1 with the first current-sense amplifier 738 of FIG. 7 divided by the known value of the shunt resistor 730 or a reading of the high-side current detector 725 of FIG. 7.

Similarly, current detection and measurement at T2 for one of the high-side switches can be completed based on the low-side current detector comprising a voltage measured at T2 with the first current-sense amplifier 738 divided by the known value of the shunt resistor 730 or a reading of the high-side current detector 725. Illustratively, here a low-side calibration measurement 816 can be triggered at mid T1 to calculate a current through S6, the active corresponding switch. Further, a high-side calibration measurement 818 can be triggered at mid T2 to calculate a current through S1.

Each pulse-width modulated signal cycle can include a one state where a corresponding switch on the high-side and the low-side can be individually activated relative to other switches on their side. Over the course of an entire electric cycle, which could be well over twenty-four pulse-width modulated signal cycles each of the switches will be measured and calibrated.

The low-side calibration measurement 816 at mid T1 will correspond to each of the low-side switches S2, S4, and S6 at least once during a single electrical cycle, which should have at least twenty four pulse-width modulated signal cycles. Similarly, the high-side calibration measurement 818 at mid T2 will correspond to each of the high-side switches S1, S3, and S5 at least once during a single electrical cycle. The current measurements at T1 and T2 can be performed by the low-side current detector, the high-side current detector 725, or a combination of both.

At T1, the current through only one of the low-side switches will be measured with the low-side current detector or with the high-side current detector 725. This is to be understood as the “corresponding switch” for the single pulse-width modulated signal cycle 802 on the low-side. Here the corresponding switch would be S6 for the low-side measurement. It is noted that at T1 both S1 and S3 are active on the high-side.

At T2, the current through only one of the high-side switches will be measured with the low-side current detector or with the high-side current detector 725. This is to be understood as the corresponding switch for the single pulse-width modulated signal cycle 802 on the high-side.

Here the corresponding switch would be S1 for the high-side measurement. It is noted that at T2 both S4 and S6 are active on the low-side. Only a single measurement at T1 for the low-side and T2 for the high-side over the pulse-width modulated signal cycle is not adequate for utilizing advanced control methods, but has been discovered to be an excellent calibration measurement for non-linear voltage of the corresponding switches.

The hybrid current sense system 700 can execute a high-side switch measurement 820 at mid T0, and a low-side switch measurement 822 at mid T3. The high-side switch measurement 820 can correspond to all high-side switches S1, S3, and S5 being turned active. The low-side switch measurement 822 can correspond to current information of all low-side switches S2, S4, and S6 being turned inactive.

The low-side switch measurement 822 can read the voltage across S2 with the second current-sense amplifier 740 of FIG. 7, across S4 with the third current-sense amplifier 742 of FIG. 7, and across S6 with the fourth current-sense amplifier 744 of FIG. 7. The high-side switch measurement 820 can read the voltage across S1 with the seventh current-sense amplifier 750 of FIG. 7, across S3 with the sixth current-sense amplifier 748 of FIG. 7, and across S5 with the fifth current-sense amplifier 746 of FIG. 7.

It is to be understood herein that the low-side switch measurement 822 of the voltage across S2, S4, and S6 and the high-side switch measurement 820 of the voltages across S1, S3, and S5 collects current information for each of the low-side switches and the high-side switches. The current information collected during the low-side switch measurement 822 and the high-side switch measurement 820 is uncalibrated.

The low-side switch measurement 822 of the voltage across S2, S4, and S6 and the high-side switch measurement 820 of the voltages across S1, S3, and S5 can be done in parallel. It will be appreciated that the voltage measured at the low-side switch measurement 822 and the high-side switch measurement 820 can be used as inputs for advanced control methods such as sensorless field-oriented control or direct torque control.

The voltage measured at the low-side switch measurement 822 and the high-side switch measurement 820 can be used to estimate currents through each of the switches but these current estimates are subject to the temperature non-linearities of FIG. 4 and the current non-linearities attributable to RON of FIG. 5. Although the current estimates are not exact, they are close enough to use the advanced control methods and can be further calibrated using the low-side calibration measurement 816 and the high-side calibration measurement 818.

During the second half of the pulse-width modulated signal cycle 802, the hybrid current sense system 700 can execute a calculation step 824. During the calculation step 824, the uncalibrated current information determined during the low-side switch measurement 822 and the high-side switch measurement 820 can be calibrated. In one contemplated method, calibrating the current information can include calculating calibration weights for the single active low-side switch of T1 and the single active high-side switch of T2.

The calibration calculation can begin by determining the measured current through the single active low-side switch measured during the low-side calibration measurement 816 and determining the measured current through the single active high-side switch during the high-side calibration measurement 818. Next the measured currents are compared with estimated currents for each of the switches.

The estimated current is calculated based on the voltage measured across the single active low-side switch during the low-side switch measurement 822 for the single active low-side switch. Similarly, the estimated current is calculated based on the voltage measured across the single active high-side switch during the high-side switch measurement 820.

It should be noted that during the low-side switch measurement 822 at T3, all low-side switches are active and the reference to the single active low-side switch only refers to the switch that was active during T1.

The measured current is compared with the estimated current, the difference being a calibration weight. The estimated current plus the calibration weight can be the calibrated current. The two high-side switches and two low-side switches that are not calibrated during the pulse-width modulated signal cycle will utilize a calibration weight from a previous cycle.

Thus, the calibrated currents for each of the low-side switches and each of the high-side switches will be updated approximately once every third pulse-width modulated signal cycle, although there are methods of increasing the number of switches per cycle.

The calibrated current for each of the switches can be used as inputs to advanced control methods such as sensorless field-oriented control and direct torque control. Position control and speed control from these advanced control methods can be calculated for each phase, or leg, based on the calibrated current for each switch.

Particularly, current through the shunt resistor 730 of the low-side current detector or through the high-side current detector 725 can be determined during T1 or T2. This current at T1 or T2 corresponds to the current through the single active low-side switch or the single active high-side switch, respectively.

In addition to calculating the calibrated current, the resistance of the single active low-side switch can be calculated by dividing the voltage measured across the single active low-side switch during T3 with the low-side switch measurement 822 by the current calculated for the single active low-side switch using the measurement during T1 with the low-side calibration measurement 816. Similarly, the resistance of the single active high-side switch can be calculated by dividing the voltage measured across the single active high-side switch during T0 with the high-side switch measurement 820 by the current calculated for the single active high-side switch using the measurement during T2 with the high-side calibration measurement 818.

The resistances can be correlated with temperature of the single active low-side switch and the single active high-side switch using the relationship shown, for example, in FIG. 4. The resistance of the single active low-side switch and the single active high-side switch can also be correlated with current with the RON relationship shown, for example, in FIG. 5. It has been discovered that the resistance can be monitored for each of the switches and any over temperatures can be detected with over temperature thresholds and reported or can be used to generate a fault code.

The hybrid current sense system 700 can perform an execution step 826 at the beginning of the single pulse-width modulated signal cycle 802, which is at the beginning of TO. During the execution step 826 the controller 702 of FIG. 7 can shift the pulse-width modulated signals for each of the six switches for position and speed control based on the readings from the previous pulse-width modulated signal cycle. Further, during the execution step 826 the controller 702 can update the calibration weight for the single active low-side switch and single active high-side switch of the previous pulse-width modulated signal cycle.

It is contemplated that the hybrid current sense system 700 could also take further calibration measurements during the pulse-width modulated signal cycle. Illustratively, for example, the hybrid current sense system 700 could also measure the current through the shunt resistor 730 of the low-side current detector or through the high-side current detector 725 during an additional low-side or high-side calibration measurement. It is further contemplated that during the low-side calibration measurement 816 a derived high-side switch current can be computed utilizing Kirchhoff's law.

During the high-side calibration measurement 818 a derived low-side switch can be derived in addition to the single active low-side switch. The current through the derived low-side switch can be determined by utilizing Kirchhoff's law. Determining the current through the derived high-side switch and derived low-side switch allows four out of the six switches to be calibrated once every pulse-width modulated signal cycle.

While the hybrid current sense system 700 has been described with regard to the controller 702 calibrating the current information with current weights and a providing a calibrated current using the controller 702 as the current calibrator, the hybrid current sense system 700 can be implemented with other methods as well. Other methods of calibrating current information can include the use of analog-to-digital converters as current calibrators for calibrating current information from the low-side switches and high-side switches, and after which, the calculations for using calibrated current information within the advanced control methods is accomplished in software or hardware.

Further methods could also include calculating a calibration error, which could be the difference between a previous calibration weight and a new calibration weight, and which can then be used to calibrate the current information by tuning a current-sense amplifier gain based on the calibration error, for example. The current calibrator for calculating the calibration error could be an amplifier or the controller 702.

Yet further methods could include calibrating the current information for both the low-side switches and the high-side switches in digital, for example in the controller 702, or in analog, for example using a digital-to-analog converter or error amplifiers. The controller 702, digital-to-analog converter, error amplifiers, or a combination thereof can therefore be used as the current calibrator.

It has been discovered that these methods have increased importance because they can each advantageously utilize the calibration readings of the shunt resistor 130 in combination with less uncalibrated current information across the switches to calibrate the current information which can be used with advanced control methods of three-phase motors.

Referring now to FIG. 9, therein is shown a flow chart for operating an embodiment of the hybrid current sense system 700 of FIG. 7. The hybrid current sense system 700 can begin by executing an initialization step 902. During the initialization step 902 calibration weights 904 can be initialized for each of the switches. Continuing with the example of FIG. 7, six calibration weights can be initialized, two for the U-phase 714, two for the V-phase 718, and two for the W-phase 722 each of FIG. 7.

The operation of the hybrid current sense system 700 can next proceed with the high-side switch measurement 820 at the middle of T0 of FIG. 8. During the high-side switch measurement 820 the voltages across each of the high-side switches are measured including an S1 voltage 906, an S3 voltage 908, and an S5 voltage 910.

After the high-side switch measurement 820, the hybrid current sense system 700 can execute the low-side calibration measurement 816 at the middle of T1 of FIG. 8. During the low-side calibration measurement 816 a single active low-side switch voltage 912 can be measured with the low-side current detector across the shunt resistor 730 of FIG. 7 with the first current-sense amplifier 738 of FIG. 7, or measured with the high-side current detector 725 of FIG. 7.

After the low-side calibration measurement 816 the hybrid current sense system 700 can execute the high-side calibration measurement 818 at the middle of T2 of FIG. 8. During the high-side calibration measurement 818 a single active high-side switch voltage 914 can be measured with the low-side current detector across the shunt resistor 730 with the first current-sense amplifier 738 or with the high-side current detector 725.

The hybrid current sense system 700 can next execute the low-side switch measurement 822 at the middle of T3 of FIG. 8. During the low-side switch measurement 822 the voltages across each of the low-side switches are measured including an S2 voltage 924, an S4 voltage 926, and an S6 voltage 928.

After the middle of T3 and during the second half of the pulse-width modulated signal cycle the hybrid current sense system 700 can perform the calculation step 824. The calculation step 824 can include many smaller calculations.

Illustratively, for example, the calculation step 824 can include a calculate estimated current step 930. During the calculate estimated current step 930 the voltages measured during the low-side switch measurement 822 and the high-side switch measurement 820 can be used to calculate estimated currents 932 for each of the three high-side switches and three low-side switches.

Furthermore, during the calculation step 824, the hybrid current sense system 700 can execute a calculate measured current step 934. During the calculate measured current step 934, a measured current can be determined whether using the low-side current detector or the high-side current detector 725.

Illustratively, for example, when the low-side current detector is used the single active low-side switch voltage 912 can be divided by the value of the shunt resistor 730 to yield a single active low-side switch measured current 936. Similarly, when the low-side current detector is used the single active high-side switch voltage 914 can be divided by the value of the shunt resistor 730 to yield a single active high-side switch measured current 938.

Two additional Kirchhoff derived currents can be calculated including a Kirchhoff derived current for a second determinable low-side switch and a second determinable high-side switch. Illustratively, when the low-side calibration measurement 816 is made during T1, the W-output 124 of FIG. 1 will be active and measured through the shunt resistor 130 of FIG. 1. The IW of FIG. 1 from the W-output 124 can be used to determine a high-side switch derived current 940, utilizing Kirchhoff's law of Equation 1. Here, the high-side switch derived current 940 can correspond to a second determinable high-side switch, and in this example the high-side switch of the W-output 124 or S5 of FIG. 1.

Similarly, when the high-side calibration measurement 818 is made during T2, S1 of FIG. 1 is active and the shunt resistor 130 measures the current IU of FIG. 1, which can be used to calculate a low-side switch derived current 942 utilizing Kirchhoff's law of Equation 1. Here, the low-side switch derived current 942 can correspond to a second determinable low-side switch, and in this example the low-side switch of the U-output 116 of FIG. 1 or S2 of FIG. 1.

Once the calculate measured current step 934 is complete, the hybrid current sense system 700 can execute a calculate calibration weights step 944. The calculate calibration weights step 944 can compare the measured currents determined in the calculate measured current step 934 with the estimated currents 932 determined in the calculate estimated current step 930.

More particularly, the difference between the single active low-side switch measured current 936 and the estimated current 932 for that switch can be the calibration weight 904 for that switch. Similarly, the differences between the single active high-side switch measured current 938, the low-side switch derived current 942, and the high-side switch derived current 940 can be compared with the estimated current 932 for the respective switch.

The calibration weights 904 for the four switches can be updated. Once the calculate calibration weights step 944 has been completed, the hybrid current sense system 700 can execute a calculate calibrated current step 946.

The calculate calibrated current step 946 can calibrate the voltage detected across the switch by summing the estimated current 932 for each switch with the calibration weight 904 for each switch to produce a calibrated current 948 for each switch. It is to be noted that when a calibration weight 904 is not calculated for each switch, a previous or initial calibration weight 904 can be summed with the estimated current 932 to determine the calibrated current 948.

It has been discovered that utilizing the estimated currents 932 allows for every switch on the high-side and on the low-side to be measured each pulse-width modulated signal cycle, which provides excellent information input into advanced control methods. The calibration of one, two, or four switches per pulse-width modulated signal cycle increases the accuracy of the advanced control method.

Once the calibrated currents 948 have been determined, the calibrated currents 948 can be used as inputs into an advanced control methods step 950. During the advanced control methods step 950, the calibrated current 948 for each of the switches can be used as inputs to advanced control methods such as sensorless field-oriented control and direct torque control. Position control and speed control from these advanced control methods can be calculated for each phase, or leg, based on the calibrated current 948 for each switch.

Once the calculation step 824 has been performed, the hybrid current sense system 700 can execute the execution step 826. During the execution step 826 the controller 702 of FIG. 7 can shift the pulse-width modulated signals for each of the six switches for position and speed control based on the calibrated currents 948 determined during the previous pulse-width modulated signal cycle. Further, during the execution step 826 the controller 702 can update the calibration weights 904 for the single active low-side switch, the single active high-side switch, the second determinable low-side switch, and the second determinable high-side switch of the previous pulse-width modulated signal cycle.

The execution step 826 can be performed at the beginning of TO. Both the calculation step 824 and the execution step 826 can be performed by a processor in the controller 92. Alternatively, some of the more complex calculations can be performed by a remote processor in communication with the controller 92. By mid T0, the hybrid current sense system 700 will again execute the high-side switch measurement 820.

It is contemplated that the calculation step 824 can further include a calculate temperature value for each of the switches determined in the calculate measured current step 934. The temperature value can be the voltages, measured during the high-side switch measurement 820 and the low-side switch measurement 822, divided by a corresponding one of the measured currents determined in calculate measured current step 934. That is, for example, the S6 voltage 928 could be divided by the single active low-side switch measured current 936 to find the resistance of S6, which corresponds to temperature as set forth in FIG. 4.

The resistance for each of the switches can be determined once the current is measured with the low-side current detector or the high-side current detector 725 for the respective switch. A resistance threshold can be used to generate a fault if the resistance of the switch exceeds the resistance threshold.

Referring now to FIG. 10, therein is shown a flow chart for manufacturing an embodiment of the hybrid current sense system. The method can comprise: coupling a high-side switch to a first phase output and coupled to a high voltage rail in a box 1002; coupling a low-side switch to a second phase output and to a low voltage rail in a box 1004; coupling an amplifier to the low-side switch and the amplifier configured to detect first current information as a first voltage drop across the low-side switch in a box 1006; coupling a second amplifier coupled to the high-side switch, the second amplifier configured to detect second current information as a second voltage drop across the high-side switch in a box 1008; coupling a current detector between the low-side switch and the low voltage rail, the current detector configured to determine a first measured current for the low-side switch and the current detector configured to determine a second measured current of the high-side switch in a box 1010; and configuring a controller as a current calibrator to calibrate the first current information for the low-side switch based on the first measured current, and to calibrate the second current information for the high-side switch based on the second measured current in a box 1012.

Thus, it has been discovered that the hybrid current sense system furnishes important and heretofore unknown and unavailable solutions, capabilities, and functional aspects allowing current information determined every pulse-width modulated signal cycle to be used with advanced control methods while calibrating the current information with the measured current reading using only a single shunt resistor, or the like.

The resulting configurations are straightforward, cost-effective, uncomplicated, highly versatile, accurate, sensitive, and effective, and can be implemented by adapting known components for ready, efficient, and economical manufacturing, application, and utilization because fewer current resistors are needed. Furthermore, the system footprint is smaller and monitoring hardware does not need to be extremely fast.

While the hybrid current sense system has been described in conjunction with a specific best mode, it is to be understood that many alternatives, modifications, and variations will be apparent to those skilled in the art in light of the preceding description. Accordingly, it is intended to embrace all such alternatives, modifications, and variations, which fall within the scope of the included claims. All matters set forth herein or shown in the accompanying drawings are to be interpreted in an illustrative and non-limiting sense.

What is claimed is:

1. A hybrid current sense system comprising:
a switch coupled to a phase output and coupled to a voltage rail;
an amplifier coupled to the switch and the amplifier configured to detect a current information of the switch;
a current detector coupled between the switch and the voltage rail, the current detector configured to determine a measured current for the switch; and
a current calibrator configured to calibrate the current information for the switch based on the measured current.

2. The system of claim 1 wherein: the current detector is a current-sense amplifier coupled to a shunt resistor.

3. The system of claim 1 wherein: the current calibrator is configured to calibrate the current information for an on-state resistance of the switch.

4. The system of claim 1 wherein: the current calibrator is configured to calibrate the current information for a temperature of the switch.

5. The system of claim 1 further comprising: an analog-to-digital converter coupled to the amplifier and the analog-to-digital converter coupled to the current calibrator with a digital output.

6. A hybrid current sense system comprising:
a high-side switch coupled to a phase output and coupled to a high voltage rail;
a low-side switch coupled to the phase output and coupled to a low voltage rail;
an amplifier coupled to the low-side switch and the amplifier configured to detect a first current information of the low-side switch;
a current detector configured to determine a measured current for the low-side switch; and
a current calibrator configured to calibrate the first current information for the low-side switch based on the measured current.

7. The system of claim 6 further comprising:
a second amplifier coupled to the high-side switch, the second amplifier configured to detect a second current information of the high-side switch; and
wherein:
the current calibrator is configured to calibrate the second current information for the high-side switch based on the measured current.

8. The system of claim 6 wherein: the current detector is configured to detect the measured current during a T1 state of a pulse-width modulated signal cycle.

9. The system of claim 6 further comprising: a controller configured to determine a temperature of the low-side switch based on the first current information of the low-side switch and the measured current.

10. The system of claim 6 wherein: the current calibrator is configured to determine a Kirchhoff derived current for the high-side switch based on the measured current.

11. A method of manufacturing a hybrid current sense system comprising:
coupling a switch to a phase output and to a voltage rail;
coupling an amplifier to the switch, the amplifier configured to detect a first current information of the switch;
configuring a current detector to determine a measured current for the switch; and
configuring a current calibrator to calibrate the first current information for the switch based on the measured current.

12. The method of claim 11 wherein: coupling the current detector includes coupling a current-sense amplifier and a shunt resistor between the switch and the voltage rail.

13. The method of claim 11 wherein: configuring the current calibrator includes configuring the current calibrator to calibrate the first current information for an on-state resistance of the switch.

14. The method of claim 11 wherein: configuring the current calibrator includes configuring the current calibrator to calibrate the first current information for a temperature of the switch.

15. The method of claim 11 further comprising: coupling an analog-to-digital converter to the amplifier and to the current calibrator, the analog-to-digital converter coupled to the current calibrator with a digital output.

16. The method of claim 11 wherein:
coupling the switch to the voltage rail includes coupling a low-side switch to a low voltage rail; and
further comprising:
coupling a high-side switch to the phase output and to a high voltage rail.

17. The method of claim 16 further comprising:
coupling a second amplifier to the high-side switch, the second amplifier configured to detect a second current information of the high-side switch; and
wherein:
configuring the current calibrator includes configuring the current calibrator to calibrate the second current information of the high-side switch based on the measured current.

18. The method of claim 16 wherein: coupling the current detector includes coupling the current detector configured to detect the measured current during a T1 state of a pulse-width modulated signal cycle.

19. The method of claim 16 further comprising: configuring a controller to determine a temperature of the low-side switch based on the first current information of the low-side switch and the measured current.

20. The method of claim 16 wherein: configuring the current calibrator includes configuring the current calibrator to determine a Kirchhoff derived current for the high-side switch based on the measured current.
